(19) United States
(12) Patent Application Publication
(10) Pub. No.: US 2026/0076065 A1
(43) Pub. Date: Mar. 12, 2026

(54) DISPLAY DEVICE INCLUDING A BLOCKING PART AND A MOLDING PART, AND ELECTRONIC DEVICE INCLUDING A DISPLAY DEVICE

(71) Applicant: SAMSUNG DISPLAY CO., LTD., YONGIN-SI (KR)

(72) Inventor: EUNAH KIM, Yongin-si (KR)

(21) Appl. No.: 19/272,440

(22) Filed: Jul. 17, 2025

(30) Foreign Application Priority Data
Sep. 10, 2024 (KR) 10-2024-0123500

(51) Int. Cl. H10K 59/80

(52) U.S. Cl. CPC H10K 59/8722

(57) ABSTRACT

A display device includes a display module, a window disposed on the display module and including a transmission region and a bezel region disposed proximate to the transmission region, a blocking part disposed below the window and overlapping the bezel region, and a molding part disposed below the window and covering the blocking part. A hardness of the blocking part is greater than a hardness of the molding part.

### CROSS-REFERENCE TO RELATED APPLICATION

This application claims priority under 35 U.S.C. § 119 to Korean Patent Application No. 10-2024-0123500, filed on Sep. 10, 2024, in the Korean Intellectual Property Office, the entire contents of which are hereby incorporated by reference.

### BACKGROUND

### 1. Technical Field

The present disclosure herein relates to a display device including a blocking part and a molding part, and an electronic device including a display device, and more particularly, to a display device and an electronic device having improved reliability.

### 2. Discussion of Related Art

A display device, such as a television, a monitor, a smartphone, or a tablet PC, may include a display panel for displaying an image. The display panel may be embodied in various forms including a liquid crystal display panel, an organic light-emitting display panel, an electrowetting display panel, or an electrophoretic display panel. The display device may include a window for protecting the display panel. The window may be attached to the display panel through a lamination process.

### SUMMARY

The present disclosure is intended to protect a display panel included in a display device and an electronic device from external impact.

An embodiment of the inventive concept provides a display device including a display module, a window disposed on the display module and including a transmission region and a bezel region disposed proximate to the transmission region, a blocking part disposed below the window and overlapping the bezel region, and a molding part disposed below the window and covering the blocking part. A hardness of the blocking part is greater than a hardness of the molding part.

In an embodiment of the inventive concept, a display device includes a display module, a window disposed on the display module and including a transmission region and a bezel region surrounding at least a portion of the transmission region, a blocking part disposed below the window and overlapping the bezel region, and a molding part disposed below the window and covering the blocking part. The blocking part includes a first surface facing the display module and a second surface disposed opposite to the first surface. The second surface includes a curved surface.

In an embodiment of the inventive concept, an electronic device includes a housing, an electronic module disposed in the housing, and a display device electrically connected to the electronic module. The display device includes a display module, a window disposed on the display module and including a transmission region and a bezel region disposed proximate to the transmission region, a blocking part disposed below the window and overlapping the bezel region, and a molding part disposed below the window and covering the blocking part. A hardness of the blocking part is greater than a hardness of the molding part.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is an assembled perspective view of an electronic device according to an embodiment of the inventive concept;

FIG. 2 is an exploded perspective view of an electronic device according to an embodiment of the inventive concept;

FIG. 3 is a cross-sectional view of a display module according to an embodiment of the inventive concept;

FIG. 4 is a plan view of a display panel according to an embodiment of the inventive concept;

FIG. 5 is a plan view of an input sensing unit according to an embodiment of the inventive concept;

FIG. 6 is a cross-sectional view of a display module according to an embodiment of the inventive concept;

FIG. 7A is a cross-sectional view of a display device, according to the inventive concept, taken along line I-I of FIG. 2;

FIG. 7B is a diagram for describing a function of a blocking part illustrated in FIG. 7A;

FIG. 8 is a cross-sectional view of a second display device DDa according to an embodiment of the inventive concept;

FIG. 9 is a cross-sectional view of a third display device DDb according to an embodiment of the inventive concept;

FIG. 10A is a cross-sectional view of a fourth display device DDc according to an embodiment of the inventive concept;

FIG. 10B is a cross-sectional view of a fifth display device DDd according to an embodiment of the inventive concept;

FIG. 10C is a cross-sectional view of a sixth display device DDe according to an embodiment of the inventive concept; and

FIG. 11 is a diagram illustrating an electronic device according to an embodiment of the present invention.

### DETAILED DESCRIPTION

Embodiments of the inventive concept may be variously modified and have various forms. Example embodiments will be illustrated in the drawings and described in detail in the description. However, this is not intended to limit the inventive concept to a specific disclosed form, and it should be understood that all changes, equivalents, and alternatives included in the spirit and scope of the inventive concept are included.

In this specification, it will be understood that when an element (or a region, a layer, a portion, or the like) is referred to as being “on”, “connected to” or “coupled to” another element, the element may be directly disposed on, connected or coupled to the other element, or an intervening element may be disposed therebetween.

Like reference numerals or symbols refer to like elements. Also, in the drawings, the thicknesses, ratios, and dimensions of the elements may be exaggerated for effective description of the technical contents.

The term “and/or” includes all of one or more combinations which may be defined by related elements.

Although the terms first, second, etc. may be used herein to describe various elements, these elements should not be limited by these terms. These terms are only used to distinguish one element from another element. For example, a first element may be referred to as a second element, and similarly, a second element may also be referred to as a first element without departing from the scope of the inventive concept. The singular forms may include the plural forms unless the context clearly indicates otherwise.

The terms such as “below”, “on lower side”, “above”, and “on upper side” may be used herein to describe the relationships of elements illustrated in the drawings. These terms have relative concepts and are described on the basis of the directions indicated in the drawings.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and are explicitly defined herein unless the terms are interpreted in an idealized or overly formal sense.

It will be understood that the terms such as “include” or “have”, when used herein, are intended to specify the presence of stated features, integers, steps, operations, elements, components, or combinations thereof, but do not preclude the presence or addition of one or more other features, integers, steps, operations, elements, components, or combinations thereof.

Hereinafter, embodiments of the inventive concept will be described with reference to the drawings.

Impacts on an exterior of a display device, such as on a housing, may be propagated directly to a display module, which may damage the display module. For example, an impact may be transferred to the display module through a window disposed on the display module. In an embodiment, a display panel may include a structure that may change a propagation direction of at least a portion of a force of an impact on an exterior of a display device. The structure may include a blocking part and a molding part disposed on a lower surface of a window, which may be disposed on the display module. For example, the structure may change a propagation direction of at least a portion of the impact to be away from the display module.

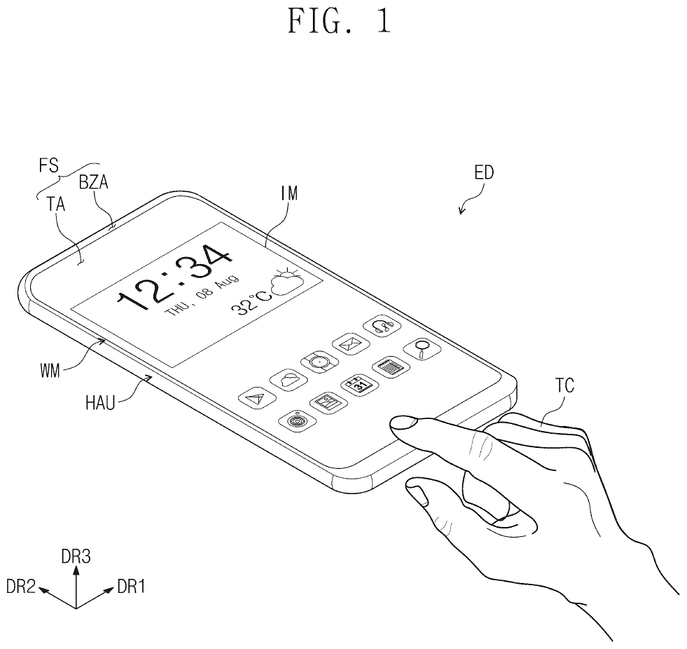

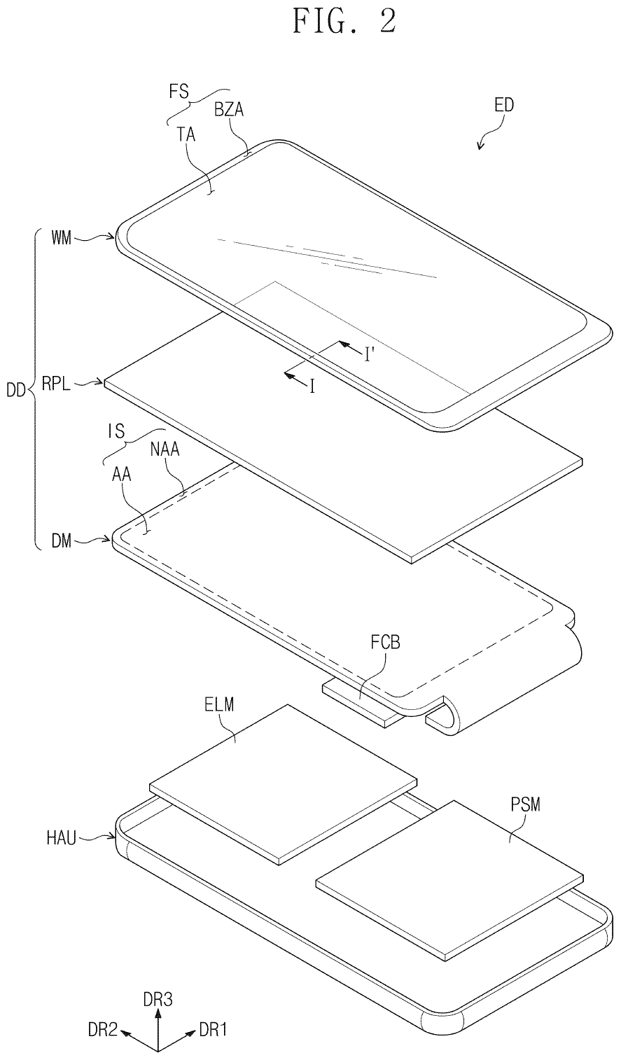

FIG. 1 is an assembled perspective view of an electronic device according to an embodiment of the inventive concept. FIG. 2 is an exploded perspective view of an electronic device according to an embodiment of the inventive concept.

Referring to FIG. 1 and FIG. 2, an electronic device ED may be activated in response to an electrical signal, display an image IM, or sense an external input TC. For example, the electronic device ED may include a device such as a monitor, a mobile phone, a tablet PC, a navigation device, or a game console. However, descriptions of the electronic device ED are provided by way of example, and are not limiting on the electronic device ED. For example, the electronic device ED is exemplarily illustrated as a mobile phone, but is not necessarily limited thereto.

The electronic device ED may have a rectangular shape having short sides extending in a first direction DR1 and long sides extending in a second direction DR2 crossing the first direction DR1 in a plan view. However, the inventive concept is not necessarily limited thereto, and the electronic device ED may have various shapes, such as a circular shape or a polygonal shape in a plan view.

In an embodiment, a third direction DR3 may be defined as a direction perpendicular to a plane defined by the first direction DR1 and the second direction DR2. A front surface (or upper surface) and a rear surface (or lower surface) of the electronic device ED may be opposed to each other in the third direction DR3, and a normal direction of each of a front surface and a rear surface may be substantially parallel to the third direction DR3. A distance between a front surface and a rear surface defined along the third direction DR3 may correspond to a thickness dimension.

As used herein, the wording “in a plan view” may be defined as a state of being viewed in the third direction DR3. As used herein, the wording “in a cross-sectional view” may be defined as a state of being viewed in the first direction DR1 or the second direction DR2. Meanwhile, directions indicated by the first to third directions DR1, DR2, and DR3 may have relative concepts and may be converted into other directions.

The electronic device ED may be rigid or flexible. The term “flexible” may mean bendable characteristics, and the electronic device ED may be a device including a structure which is completely foldable to a structure which is bendable to a level of several nanometers. For example, the flexible electronic device ED may include a curved electronic device, a rollable electronic device, or a foldable electronic device.

The electronic device ED may display an image IM through a display surface FS. At least a portion of display surface FS may be disposed parallel to each of the first direction DR1 and the second direction DR2. The image IM may include a static image or a dynamic image. FIG. 1 illustrates a clock and icons as an example of the image IM.

The display surface FS of the electronic device ED may include a flat surface or may further include a curved surface bent from at least one side of the flat surface. The display surface FS may correspond to a front surface of the electronic device ED. The display surface FS may correspond to a front surface of a window WM. Hereinafter, the display surface FS of the electronic device ED and the front surface FS of the window WM may be denoted as the same reference numerals or symbols unless the context clearly indicates otherwise.

The electronic device ED according to an embodiment may sense the external input TC applied from the outside. The external input TC may include inputs in various forms such as force, pressure, temperature, or light. In an embodiment, the external input TC is illustrated as a user's hand applied to the front surface of the electronic device ED. However, this is illustrated as an example, and the external input TC may include contact by a pen applied close to the electronic device ED or an input, such as hovering, detected by the electronic device ED.

The electronic device ED may sense a user's input through the display surface FS defined on the front surface FS and respond to a sensed input signal. However, a region, for sensing the external input TC, of the electronic device ED is not necessarily limited to the front surface FS of the electronic device ED and may be changed according to design of the electronic device ED. For example, the electronic device ED may sense a user's input applied to a side surface or a rear surface of the electronic device ED.

The electronic device ED may include at least one of a display device DD, an electronic module ELM, a power module PSM, or a housing HAU. The window WM and the housing HAU may be coupled to form an exterior of the electronic device ED. The display device DD may include at least one of the window WM, an optical layer RPL, or a display module DM.

The window WM may be disposed on the display module DM. The window WM may cover the display module DM. The window WM may protect the display module DM from external impact and scratches.

The window WM may include an optically transparent insulating material. For example, the window WM may include glass or synthetic resin as a base film. The window WM may have a single-layered or multi-layered structure. For example, the window WM having a multi-layered structure may include synthetic resin films coupled with an adhesive or a glass film and a synthetic resin film coupled with an adhesive. The window WM may further include a functional layer such as a hard coating layer, a phase control layer, or an anti-fingerprint layer disposed on a transparent base film.

The front surface FS of the window WM may correspond to the front surface FS of the electronic device ED. The front surface FS of the window WM may include a transmission region TA and a bezel region BZA.

The transmission region TA may be an optically transparent region. The transmission region TA may transmit light that is provided by the display module DM. The light may form the image IM. In an embodiment, the transmission region TA is illustrated in a quadrangular shape, but is not necessarily limited thereto and may have various other shapes.

The bezel region BZA may be a region having a lower light transmittance than the transmission region TA. The bezel region BZA may correspond to a region in which a material having a predetermined color is printed. The bezel region BZA may reduce or prevent transmission of light, and may thus reduce or prevent a component of the display module DM disposed to overlap the bezel region BZA from being viewed from the outside.

The bezel region BZA may be adjacent to the transmission region TA. A shape of the transmission region TA may be substantially defined by the bezel region BZA. For example, the bezel region BZA may be disposed outside the transmission region TA and may surround the transmission region TA. However, this is illustrated as an example, and the bezel region BZA may be adjacent to one side of the transmission region TA or may be disposed on a side surface, not a front surface, of the electronic device ED. For example, the bezel region BZA may surround a portion of the transmission region TA. In addition, the bezel region BZA may be omitted.

The optical layer RPL may be disposed on a rear surface the display module DM. As illustrated, the optical layer RPL may be disposed between the display module DM and the window WM. The optical layer RPL may reduce reflectance of light incident from the outside. The optical layer RPL may include a retarder and/or a polarizer. The optical layer RPL may include at least a polarizing film. In this case, the optical layer RPL may be attached to the window WM through an adhesive layer. However, this is an example, and an embodiment of the inventive concept is not necessarily limited thereto. For example, the optical layer RPL may include a color filter.

The display module DM may be disposed between the window WM and the housing HAU. The display module DM may display the image IM and sense the external input TC. The image IM may be displayed on a front surface IS of the display module DM. The front surface IS of the display module DM may include an active region AA and a peripheral region NAA. A hardness of the optical layer RPL may be greater than a hardness of the display module DM.

The active region AA may be a region activated in response to an electrical signal. For example, the active region AA may be a region in which the image IM may be displayed and simultaneously a region in which the external input TC may be sensed. The active region AA may overlap at least a portion of the transmission region TA. Accordingly, a user may view the image IM or provide the external input TC through the transmission region TA. However, this is an example, and a region in which the image IM is displayed and a region in which the external input TC is sensed may be separated from each other in the active region AA, and the active region AA is not limited to any one embodiment.

The peripheral region NAA may be adjacent to the active region AA. For example, the peripheral region NAA may surround at least a portion of the active region AA. A driving circuit, a driving line, or the like for driving the active region AA may be disposed in the peripheral region NAA. The peripheral region NAA may overlap at least a portion of the bezel region BZA. Components disposed in the peripheral region NAA may be covered by the bezel region BZA. For example, components disposed in the peripheral region NAA may may be at least partially shielded from being viewed from the outside by the bezel region BZA.

The display module DM may include a display panel and an input sensing unit. The display panel may display the image IM, and the input sensing unit may sense the external input TC.

A portion of the display module DM may be bent with respect to a bending axis extending in the first direction DR1. The portion of the display module DM may be bent toward a rear surface of the display module DM For example, a portion of the peripheral region NAA may be bent toward a rear surface of the display module DM and overlap at least a portion of the active region AA. A flexible circuit board FCB may be connected to a portion of the bent display module DM, and the flexible circuit board FCB may overlap the display module DM in a plan view.

The flexible circuit board FCB may be electrically connected to the display module DM. For example, The flexible circuit board FCB may be electrically connected to the display module DM on one side of the display module DM. The flexible circuit board FCB may generate an electrical signal which may be provided to the display module DM or may receive a signal which may be generated in the display module DM. The flexible circuit board FCB may calculate a value including information about a position at which the external input TC is sensed or intensity of the external input TC.

The electronic module ELM and the power module PSM may be disposed on the rear surface of the display module DM. For example, the electronic module ELM and the power module PSM may be disposed below the display module DM. The electronic module ELM and the power module PSM may be electrically connected through a separate circuit board.

The power module PSM may supply power for an operation of the electronic device ED. For example, the power module PSM may include a battery module.

The electronic module ELM may include one or more functional modules that operate the electronic device ED. For example, the electronic module ELM may include a control module, a wireless communication module, an image input module, a sound input module, a sound output module, a memory, an optical module, or an external interface module. The electronic module ELM may include a main circuit board, and the modules of the electronic module ELM may be mounted on the main circuit board or may be electrically connected to the main circuit board through a separate circuit board.

The control module of the electronic module ELM may control an overall operation of the electronic device ED. For example, the control module may activate or deactivate the display module DM in accordance with a user's input. The control module may include at least one microprocessor. The optical module of the electronic module ELM may include a camera module, a proximity sensor, a biometric sensor which recognizes part (for example, a fingerprint, an iris, or a face) of a user's body, or a lamp which outputs light.

The housing HAU may be coupled to the window WM and may provide an inner space that accommodates the display module DM, the electronic module ELM, the power module PSM, and the flexible circuit board FCB. The housing HAU may include a material having relatively high rigidity. For example, the housing HAU may include one or more frames and/or plates including glass, plastic, or metal, or a combination thereof. The housing HAU may protect components of the electronic device ED accommodated in the housing HAU. For example, the housing HAU may protect components of the electronic device ED accommodated in the housing HAU by absorbing impact applied from the outside or preventing foreign substances/moisture, etc., from penetrating from the outside.

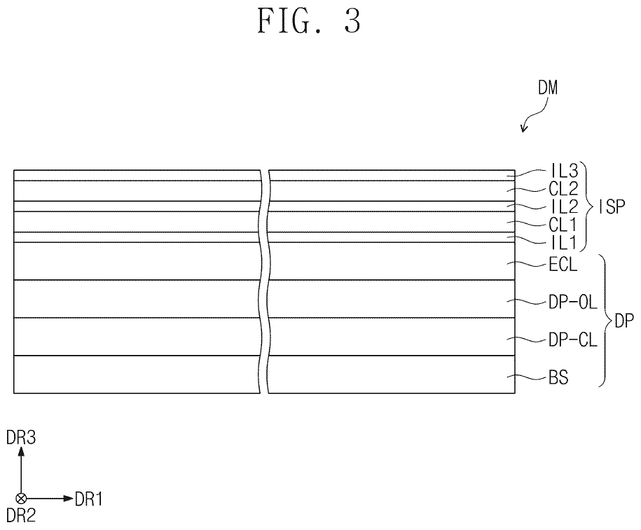

FIG. 3 is a cross-sectional view of a display module according to an embodiment of the inventive concept.

Referring to FIG. 3, a display module DM may include a display panel DP and an input sensing unit ISP. The input sensing unit ISP may be disposed on the display panel DP. For example, the input sensing unit ISP may be directly disposed on the display panel DP. In an embodiment, the wording “the input sensing unit ISP is directly disposed on the display panel DP” means that the input sensing unit ISP may be disposed on the display panel DP though a continuous process and the input sensing unit ISP and the display panel DP are coupled without a separate adhesive layer. That is, components of the input sensing unit ISP may be disposed on a base surface which is provided by the display panel DP.

The display panel DP may display an image in response to an electrical signal. The display panel DP according to an embodiment may be an emissive display panel, but is not particularly limited thereto. For example, the display panel DP may be an organic light-emitting display panel, an inorganic light-emitting display panel, or a quantum dot light-emitting display panel. An emission layer of the organic light-emitting display panel may include an organic light-emitting material. An emission layer of the inorganic light-emitting display panel may include an inorganic light-emitting material. An emission layer of the quantum dot light-emitting display panel may include quantum dots or quantum rods. Hereinafter, non-limiting examples of the display panel DP will be described in the context of an organic light-emitting display panel.

The display panel DP may include a base substrate BS, a circuit element layer DP-CL, a light-emitting element layer DP-OL, and an encapsulation layer ECL which are sequentially stacked along the third direction DR3.

The base substrate BS may be a rigid substrate or a flexible substrate that may be bendable, foldable, or rollable. For example, the base substrate BS may be a glass substrate, a metal substrate, or a polymer substrate. The base substrate BS may provide a base surface on which the circuit element layer DP-CL is disposed.

The base substrate BS may include an inorganic layer, an organic layer, or a composite material layer. The base substrate BS may have a single-layered or multi-layered structure. For example, the base substrate BS having a multi-layered structure may include synthetic resin layers and a multi-layered or single-layered inorganic layer disposed between the synthetic resin layers. The synthetic resin layer may include an acrylic resin, a methacrylic resin, a polyisoprene-based resin, a vinyl-based resin, an epoxy-based resin, a urethane-based resin, a cellulose-based resin, a siloxane-based resin, a polyamide-based resin, or a perylene-based resin, but a material of the synthetic resin layer is not necessarily limited thereto.

The circuit element layer DP-CL may be disposed on the base substrate BS. The circuit element layer DP-CL may include at least one insulating layer, a semiconductor pattern, and a conductive pattern. An insulating layer, the semiconductor pattern, and the conductive pattern included in the circuit element layer DP-CL may form driving elements such as a transistor, signal lines, or pads.

The light-emitting element layer DP-OL may be disposed on the circuit element layer DP-CL. The light-emitting element layer DP-OL may include light-emitting elements, each configured to emit light. For example, the light-emitting elements may include an organic light-emitting element, an inorganic light-emitting element, a micro-LED, or a nano-LED. The light-emitting elements of the light-emitting element layer DP-OL may be electrically connected to driving elements of the circuit element layer DP-CL and may emit light in response to an electrical signal provided by the driving elements.

The encapsulation layer ECL may be disposed on the light-emitting element layer DP-OL and may encapsulate the light-emitting elements. The encapsulation layer ECL may include at least one thin film, which may improve optical efficiency of the light-emitting element layer DP-OL or protect the light-emitting element layer DP-OL. For example, the encapsulation layer ECL may include at least one of an inorganic film or an organic film. The inorganic film of the encapsulation layer ECL may protect the light-emitting elements from moisture/oxygen. The organic film of the encapsulation layer ECL may protect the light-emitting elements from foreign substances such as dust particles.

The input sensing unit ISP may sense an external input and may provide an input signal including information about the external input. For example, the display panel DP may display an image corresponding to the external input. The input sensing unit ISP may be driven using any of various methods such as a capacitive method, a resistive film method, an infrared method, a sound wave method, or a pressure method, and a driving method of the input sensing unit ISP is not necessarily limited to any one method. In an embodiment, the input sensing unit ISP may be an input sensing panel driven using a capacitive method.

The input sensing unit ISP may include a base layer IL1, a first sensing conductive layer CL1, a first sensing insulating layer IL2, a second sensing conductive layer CL2, and a second sensing insulating layer IL3, which may be sequentially stacked along the third direction DR3. The base layer IL1 of the input sensing unit ISP may be in contact with the encapsulation layer ECL. However, an embodiment is not necessarily limited thereto, and at least one of the base layer IL1 or the second sensing insulating layer IL3 may be omitted.

The first sensing conductive layer CL1 and the second sensing conductive layer CL2 may each have a single-layered or multi-layered structure. The conductive layer having a multi-layered structure may include transparent conductive layers and metal layers. The metal layers of the conductive layer having a multi-layered structure may include different metals. The transparent conductive layer may include at least one of indium tin oxide (ITO), indium zinc oxide (IZO), zinc oxide (ZnO), indium tin zinc oxide (ITZO), PEDOT, metal nanowire, or graphene. The metal layer may include at least one of molybdenum, silver, titanium, copper, or aluminum, or alloy thereof. For example, the first sensing conductive layer CL1 and the second sensing conductive layer CL2 may each have a double-layered structure, for example, a double-layered structure of ITO/copper, but are not necessarily limited thereto and may each have a triple-layered structure of titanium/aluminum/titanium.

The first sensing conductive layer CL1 and the second sensing conductive layer CL2 may each include sensing conductive patterns. The sensing conductive patterns of the first sensing conductive layer CL1 and the second sensing conductive layer CL2 may form sensing electrodes constituting the input sensing unit ISP and sensing lines connected to the sensing electrodes.

The base layer IL1, the first sensing insulating layer IL2, and the second sensing insulating layer IL3 may each include at least one of an inorganic film or an organic film. For example, the inorganic film may include at least one of aluminum oxide, titanium oxide, silicon oxide, silicon oxynitride, zirconium oxide, or hafnium oxide, and the organic film may include at least one of an acrylic resin, a methacrylic resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin. However, a material of the inorganic film and the organic film is not necessarily limited thereto. In an embodiment, the base layer IL1 may include an inorganic film, and the first sensing insulating layer IL2 and the second sensing insulating layer IL3 may include an organic film, but an embodiment is not necessarily limited thereto.

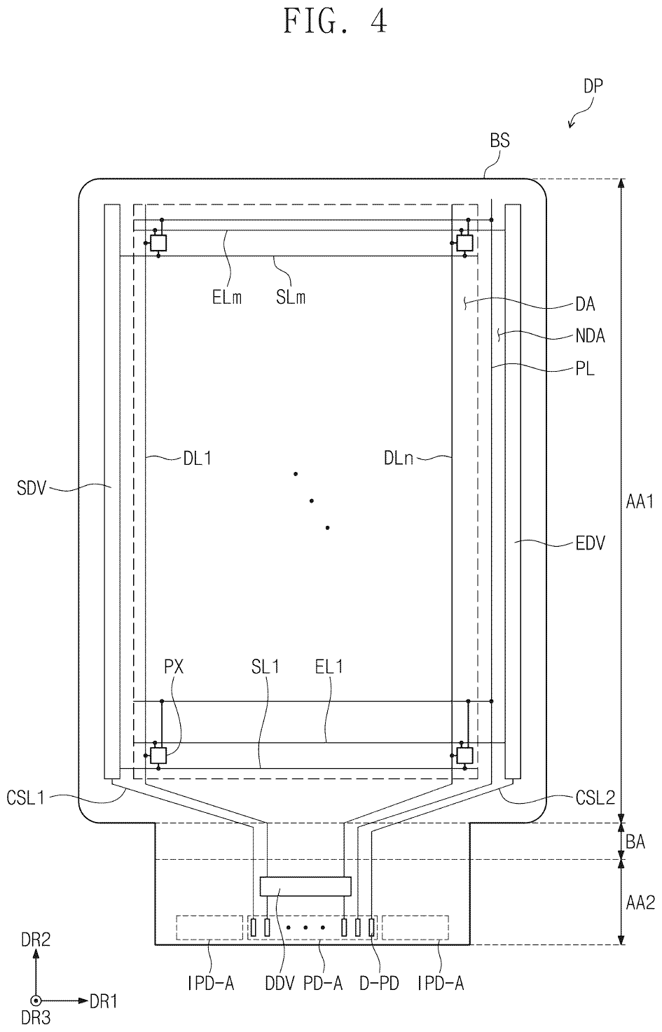

FIG. 4 is a plan view of a display panel according to an embodiment of the inventive concept.

Referring to FIG. 4, a display panel DP may include a base substrate BS, pixels PX, a plurality of signal lines, a scan driver SDV, an emission driver EDV, a data driver DDV, and display pads D-PD. The plurality of signal lines may include scan lines SL1 to SLm, data lines DL1 to DLn, emission lines EL1 to ELm, first and second control lines CSL1, CSL2, and a power line PL. Here, m and n represent natural numbers.

The base substrate BS may provide a base surface on which electrical elements and lines of the display panel DP may be disposed. The base substrate BS may include a first base region AA1, a bending region BA, and a second base region AA2. The first base region AA1, the bending region BA, and the second base region AA2 may be adjacent to each other in the second direction DR2. The bending region BA may extend from the first base region AA1 in the second direction DR2. The second base region AA2 may extend from the bending region BA in the second direction DR2. Thus, the first base region AA1 and the second base region AA2 may be spaced apart with the bending region BA disposed therebetween.

A first portion of the first base region AA1 may include a display region DA. The display region DA may be a region in which light-emitting elements of the pixels PX are disposed. Accordingly, the pixels PX may display an image through the display region DA. The display region DA may correspond to the active region AA (see FIG. 2) of the display module DM (see FIG. 2) and overlap the transmission region TA (see FIG. 2) of the window WM (see FIG. 2).

A second portion of the first base region AA1 excluding the display region DA, the bending region BA, and the second base region AA2 may be defined as a non-display region NDA. The non-display region NDA may be a region which is adjacent to the display region DA and in which an image is not displayed. The non-display region NDA may surround at least a portion of the display region DA. The scan driver SDV, the emission driver EDV, and the data driver DDV for driving the pixels PX and the display pads D-PD electrically connected to the signal lines may be disposed in the non-display region NDA. At least some of the signal lines electrically connected to the pixels PX may be disposed extending to the non-display region NDA.

The bending region BA may be a region bent with respect to a bending axis extending in the first direction DR1. That is, the bending region BA may be bent toward a rear surface of the display panel DP corresponding to the first base region AA1. As the bending region BA is bent, the second base region AA2 extending from a side of the bending region BA may overlap the first base region AA1 in a plan view. That is, the second base region AA2 may be disposed on the rear surface of the display panel DP corresponding to the first base region AA1.

In the first direction DR1, a width of each of the bending region BA and the second base region AA2 may be smaller than a width of the first base region AA1. The bending region BA may have a smaller width than the first base region AA1 in a direction parallel to the bending axis, and the bending region BA may be easily bent. However, this is illustrated as an example, and an embodiment of the inventive concept is not necessarily limited thereto. For example, in the first direction DR1, at least one of a width of the bending region BA or a width of the second base region AA2 may be equal to a width of the first base region AA1.

The second base region AA2 may be a flat region which is disposed below the first base region AA1, for example, following bending of the bending region BA. The second base region AA2 may be a region in which the data driver DDV and signal lines extending toward the display pads D-PD via the bending region BA among the signal lines are disposed.

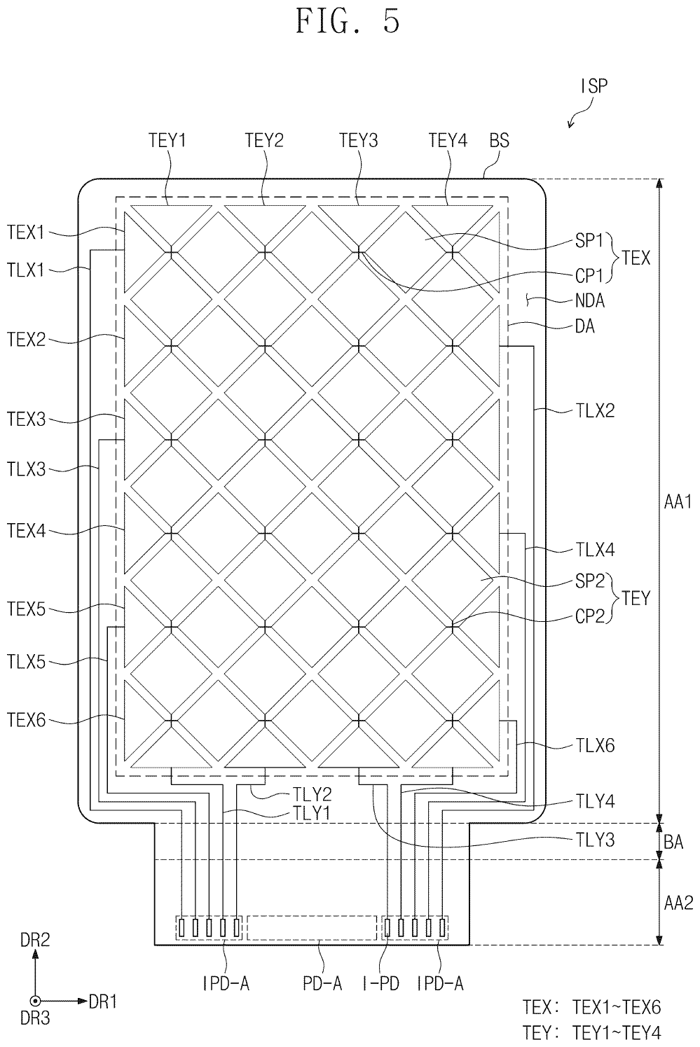

A region in which the display pads D-PD are disposed may be classified as a display pad region PD-A. A region in which sensing pads I-PD (see FIG. 5) are disposed may be classified as a sensing pad region IPD-A. FIG. 4 exemplarily illustrates that the display pad region PD-A and the sensing pad region IPD-A may be proximate in the first direction DR1. For example, the sensing pad region IPD-A may be provided to be proximate to two sides of the second base region AA2 in the first direction DR1, and the display pad region PD-A may be provided at a center portion. However, an embodiment is not necessarily limited thereto, and arrangement positions of the display pads D-PD and the sensing pads I-PD (see FIG. 5) may be variously changed.

The flexible circuit board FCB (see FIG. 2) may be disposed on the second base region AA2 in which the display pads D-PD and the sensing pads I-PD (see FIG. 5) are disposed and may be electrically connected to the display pads D-PD and the sensing pads I-PD (see FIG. 5). The flexible circuit board FCB (see FIG. 2) disposed to be proximate to a lower end portion of the second base region AA2 may be disposed on a rear surface of the display panel DP as the bending region BA is bent. The second base region AA2 and the flexible circuit board FCB (see FIG. 2) may be disposed below the first base region AA1 on the front surface of the electronic device ED (see FIG. 2), and thus a bezel area of the electronic device ED (see FIG. 2) may be reduced.

The pixels PX may each include a pixel driving circuit configured with transistors (for example, a switching transistor, a driving transistor, etc.) and at least one capacitor and a light-emitting element electrically connected to the pixel driving circuit. The pixels PX may generate light in response to an electrical signal applied to each of the pixels PX and may display an image through the display region DA based on the light generated. According to an embodiment, some of the pixels PX may include a transistor disposed in the non-display region NDA, but an embodiment of the inventive concept is not necessarily limited to any one embodiment.

The scan driver SDV and the emission driver EDV may be disposed in the non-display region NDA corresponding to the first base region AA1. The scan driver SDV and the emission driver EDV may be disposed opposing each other in the first base region AA1 with the display region DA disposed therebetween. The data driver DDV may be disposed in the non-display region NDA corresponding to the second base region AA2. In an embodiment, the data driver DDV may be an integrated circuit chip mounted in the non-display region NDA of the display panel DP. However, an embodiment of the inventive concept is not necessarily limited thereto, and the data driver DDV may be mounted on the flexible circuit board FCB (see FIG. 2).

The data lines DL1 to DLn may cross the scan lines SL1 to SLm and the emission lines EL1 to ELm. For example, the scan lines SL1 to SLm may extend in the first direction DR1 to be electrically connected to the scan driver SDV. The data lines DL1 to DLn may extend in the second direction DR2 to be electrically connected to the data driver DDV. The emission lines EL1 to ELm may extend in the first direction DR1 to be electrically connected to the emission driver EDV. Crossing signal lines may be insulated from each other.

The power line PL may include a first portion extending in the first direction DR1 and a second portion extending in the second direction DR2. The first portion extending in the first direction DR1 and the second portion extending in the second direction DR2 of the power line PL may be disposed on different layers or may be integrally disposed on the same layer. The first portion of the power line PL extending in the first direction DR1 may be electrically connected to the pixels PX and the second portion extending in the second direction DR2. The portion second of the power line PL extending in the second direction DR2 may be disposed in the non-display region NDA and may be electrically connected to the display pads D-PD via the bending region BA and the second base region AA2 from the first base region AA1. The power line PL may provide a first voltage to the pixels PX.

The first control line CSL1 may be electrically connected to the scan driver SDV. The first control line CSL1 may extend toward the lower end portion of the second base region AA2 via the bending region BA. The second control line CSL2 may be electrically connected to the emission driver EDV. The second control line CSL2 may extend toward the lower end portion of the second base region AA2 via the bending region BA.

The display pads D-PD may be disposed to be proximate to the lower end portion of the second base region AA2. On the second base region AA2, the display pads D-PD may be disposed closer to a lower end portion of the base substrate BS than the data driver DDV. The display pads D-PD may be disposed to be spaced apart along the first direction DR1. The power line PL, the first control line CSL1, and the second control line CSL2 may be each electrically connected to a corresponding display pad D-PD among the display pads D-PD. The data lines DL1 to DLn may be each electrically connected to a corresponding display pad D-PD among the display pads D-PD through the data driver DDV.

The display pads D-PD may be electrically connected to the flexible circuit board FCB (see FIG. 2) through an adhesive layer, and an electrical signal which is provided in the flexible circuit board FCB (see FIG. 2) may be transmitted to the display panel DP through the display pads D-PD. However, a method of connecting the display pads D-PD and the flexible circuit board FCB (see FIG. 2) is not necessarily limited thereto.

The scan driver SDV may generate scan signals in response to a scan control signal. The scan signals may be applied to the pixels PX through the scan lines SL1 to SLm. The data driver DDV may generate data voltages corresponding to image signals in response to a data control signal. The data voltages may be applied to the pixels PX through the data lines DL1 to DLn. The emission driver EDV may generate emission signals in response to an emission control signal. The emission signals may be applied to the pixels PX through the emission lines EL1 to ELm.

The pixels PX may be provided with the data voltages in response to the scan signals. The pixels PX may generate an image by emitting light having a luminance corresponding to the data voltages in response to the emission signals. Emission time of the pixels PX may be controlled by the emission signals.

FIG. 5 is a plan view of an input sensing unit according to an embodiment of the inventive concept. For convenience of description, FIG. 5 schematically illustrates components of an input sensing unit ISP disposed on the base substrate BS described herein.

In an embodiment, the input sensing unit ISP may be driven using a mutual capacitance method. Referring to FIG. 5, the input sensing unit ISP may include first sensing electrodes TEX: TEX1 to TEX6, second sensing electrodes TEY: TEY1 to TEY4, first sensing lines TLX1 to TLX6, second sensing lines TLY1 to TLY4, and sensing pads I-PD. However, an embodiment of the inventive concept is not necessarily limited thereto, and the input sensing unit ISP may be driven using a self-capacitance method.

The first sensing electrodes TEX may each extend along the first direction DR1 and may be arranged along the second direction DR2. FIG. 5 exemplarily illustrates six first sensing electrodes TEX1 to TEX6. However, the number of the first sensing electrodes TEX included in the input sensing unit ISP is not necessarily limited thereto. One first sensing electrode TEX may include first sensing patterns SP arranged along the first direction DR1 and first connection patterns CP1 connecting the first sensing patterns SP1.

The second sensing electrodes TEY may each extend along the second direction DR2 and may be arranged along the first direction DR1. FIG. 5 exemplarily illustrates four second sensing electrodes TEY1 to TEY4. However, the number of the second sensing electrodes TEY included in the input sensing unit ISP is not necessarily limited thereto. One second sensing electrode TEY may include second sensing patterns SP2 arranged along the second direction DR2 and second connection patterns CP2 connecting the second sensing patterns SP2.

The first sensing electrodes TEX and the second sensing electrodes TEY may be electrically insulated. The input sensing unit ISP may sense an external input through a change in capacitance between the first sensing electrodes TEX and the second sensing electrodes TEY. The first sensing electrodes TEX and the second sensing electrodes TEY may be disposed in a region corresponding to the display region DA of the base substrate BS. Accordingly, the electronic device ED (see FIG. 1) may display an image through the display region DA and simultaneously sense an external input applied to the display region DA.

The first sensing lines TLX1 to TLX6 may be disposed on the non-display region NDA and may be respectively electrically connected to the first sensing electrodes TEX1 to TEX6. Some of the first sensing lines TLX1 to TLX6 may be disposed on a left side of the non-display region NDA, and the others may be disposed on a right side of the non-display region NDA. For example, the first sensing lines TLX1, TLX3, and TLX5 connected to the first sensing electrodes TEX1, TEX3, and TEX5 disposed in odd-numbered rows may be respectively connected to left sides of the first sensing electrodes TEX1, TEX3, and TEX5, and the first sensing lines TLX2, TLX4, and TLX6 connected to the first sensing electrodes TEX2, TEX4, and TEX6 disposed in even-numbered rows may be respectively connected to right sides of the first sensing electrodes TEX2, TEX4, and TEX6. However, arrangement of the first sensing lines TLX1 to TLX6 is not necessarily limited thereto, and all the first sensing lines TLX1 to TLX6 may be disposed on the left side of the non-display region NDA or may be disposed on the right side of the non-display region NDA.

The first sensing lines TLX1 to TLX6 may each extend toward the second base region AA2 via the bending region BA from the first base region AA1. The first sensing lines TLX1 to TLX6 may be electrically connected to the sensing pads I-PD disposed on the second base region AA2.

The second sensing lines TLY1 to TLY4 may be disposed on the non-display region NDA and may be respectively electrically connected to the second sensing electrodes TEY1 to TEY4. Some of the second sensing lines TLY1 to TLY4 may be disposed to be proximate to the left side of the non-display region NDA, and others may be disposed to be proximate to the right side of the non-display region NDA. For example, in the first direction DR1, the second sensing lines TLY1 and TLY2 electrically connected to the second sensing electrodes TEY1 and TEY2 disposed on a left side among the second sensing electrodes TEY1 to TEY4 may be disposed to be proximate to a left side of the first base region AA1, and the second sensing lines TLY3 and TLY4 electrically connected to the second sensing electrodes TEY3 and TEY4 disposed on a right side may be disposed to be proximate to a right side of the first base region AA1. However, arrangement of the second sensing lines TLY1 to TLY4 is not necessarily limited thereto.

The second sensing lines TLY1 to TLY4 may each extend toward the second base region AA2 via the bending region BA from a region adjacent to a lower end portion of the first base region AA1. The second sensing lines TLY1 to TLY4 may be electrically connected to the sensing pads I-PD disposed on the second base region AA2.

Some of the sensing pads I-PD may be disposed in a region proximate to a left side of the second base region AA2 in the first direction DR1, and others may be disposed in a region proximate to a right side of the second base region AA2 in the first direction DR1. For example, the sensing pads I-PD may be divided into two groups spaced apart with the display pad region PD-A therebetween. However, arrangement of the sensing pads I-PD is not necessarily limited thereto.

The sensing pads I-PD may be disposed at the same layer as the display pads D-PD (see FIG. 4). The sensing pads I-PD may be disposed on a layer different from that of the first and second sensing lines TLX1 to TLX6 and TLY1 to TLY4 and may be connected to the first and second sensing lines TLX1 to TLX6 and TLY1 to TLY4 through a contact hole. However, an embodiment of the inventive concept is not necessarily limited thereto, and the sensing pads I-PD may be disposed on a layer different from that of the display pads D-PD (see FIG. 4). For example, the sensing pads I-PD may be integrally formed with the first and second sensing lines TLX1 to TLX6 and TLY1 to TLY4 at the same layer.

The first and second sensing lines TLX1 to TLX6 and TLY1 to TLY4 may be disposed above components of the display panel DP (see FIG. 4) on a region corresponding to the non-display region NDA of the base substrate BS. Accordingly, the first and second sensing lines TLX1 to TLX6 and TLY1 to TLY4 may overlap components of the display panel DP (see FIG. 4) on the bending region BA and the second base region AA2.

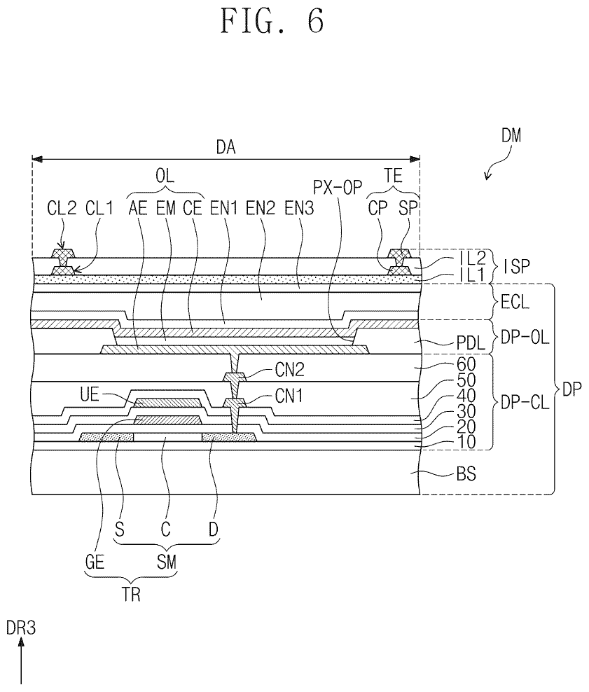

FIG. 6 is a cross-sectional view of a display module according to an embodiment of the inventive concept. For example, FIG. 6 exemplarily illustrates a cross section of the pixel PX (see FIG. 4) disposed in a display region DA.

Referring to FIG. 6, a display module DM may include a display panel DP and an input sensing unit ISP disposed on the display panel DP. Descriptions of the display panel DP, input sensing unit ISP, and the display panel DP are provided herein, and repetitive descriptions hereinafter may be simplified or omitted.

As described with reference to FIG. 3, the display panel DP may include a base substrate BS, a circuit element layer DP-CL, a light-emitting element layer DP-OL, and an encapsulation layer ECL.

The base substrate BS may have an insulating property and provide a base surface on which components of the display module DM may be disposed. The base substrate BS may have flexibility so as to be bendable. As described herein, the base substrate BS may include the first base region AA1 (see FIG. 4), the bending region BA (see FIG. 4), and the second base region AA2 (see FIG. 4), and the bending region BA (see FIG. 4) of the base substrate BS may be bent to have at least a portion of the second base region AA2 disposed below at least a portion of the first base region AA1.

The circuit element layer DP-CL may include a plurality of insulating layers disposed on the base substrate BS, a transistor TR of the pixel (see FIG. 4), an upper electrode UE, and connection electrodes CN1 and CN2. The plurality of insulating layers may include a first insulating layer 10, a second insulating layer 20, a third insulating layer 30, a fourth insulating layer 40, a fifth insulating layer 50, and a sixth insulating layer 60 sequentially stacked on the base substrate BS along a thickness direction. However, an embodiment of the first to sixth insulating layers 10 to 60 included in the circuit element layer DP-CL is not necessarily limited thereto and may be changed according to a configuration of, or a manufacturing process for, the circuit element layer DP-CL.

The first insulating layer 10 may be disposed on the base substrate BS. The first insulating layer 10 may be provided as a buffer layer and/or a barrier layer for inhibiting or preventing foreign substances from being introduced from the outside. The first insulating layer 10 may improve a bonding force between the base substrate BS and a conductive pattern and/or a semiconductor pattern SM of the circuit element layer DP-CL. The first insulating layer 10 may include at least one of a silicon oxide layer or a silicon nitride layer. In an embodiment, the first insulating layer 10 may include silicon oxide layers and silicon nitride layers, which may be alternately stacked.

The pixel PX (see FIG. 4) may be disposed on the base substrate BS. The pixel PX (see FIG. 4) may be disposed in correspondence to the display region DA. The pixel PX (see FIG. 4) may include the transistor TR and a light-emitting element OL.

The transistor TR may include the semiconductor pattern SM and a gate electrode GE. The semiconductor pattern SM may be disposed on the first insulating layer 10. The semiconductor pattern SM may include a channel C, a source S, and a drain D. The semiconductor pattern SM may include a silicon semiconductor, and may include a single crystal silicon semiconductor, a poly silicon semiconductor, or an amorphous silicon semiconductor. An embodiment of the inventive concept is not necessarily limited thereto, and the semiconductor pattern SM may include an oxide semiconductor. The semiconductor pattern SM according to an embodiment of the inventive concept may be formed of various materials, and is not necessarily limited to any one embodiment.

The semiconductor pattern SM may include a plurality of regions, which may have different electrical properties. For example, the electrical properties may differ according to the presence or absence of dopants. For example, a metal oxide may be doped into n- or p-type conductivity, or heavily doped to act as a conductor with low resistivity. For example, the semiconductor pattern SM may include a region having high conductivity due to doping of a metal oxide, and the region having high conductivity may serve as a signal line or an electrode of the transistor TR and may correspond to a source S and a drain D of the transistor TR. The semiconductor pattern SM may include an undoped region having relatively low conductivity, and the undoped region may correspond to a channel C (or an active region) of the transistor TR.

The second insulating layer 20 may be disposed on the first insulating layer 10 and cover the semiconductor pattern SM. The gate electrode GE may be disposed on the second insulating layer 20. The second insulating layer 20 may be disposed between the semiconductor pattern SM and the gate electrode GE of the transistor TR. The gate electrode GE may overlap the channel C of the semiconductor pattern SM in a plan view. The gate electrode GE may function as a mask in a process of doping the semiconductor pattern SM. The gate electrode GE may include heat-resistant molybdenum (Mo), molybdenum-containing alloy, titanium (Ti), or titanium-containing alloy, but an embodiment of the inventive concept is not necessarily limited thereto.

A structure of the transistor TR illustrated in FIG. 6 is an example, and the source S or the drain D of the transistor TR may be electrodes that are independently formed from the semiconductor pattern SM. In this case, the source S and the drain D may be in contact with the semiconductor pattern SM or may penetrate an insulating layer to be connected to the semiconductor pattern SM. In addition, the gate electrode GE may be disposed below the semiconductor pattern SM. The transistor TR according to an embodiment of the inventive concept may be formed having various structures and is not limited to any one embodiment.

The second insulating layer 20 and the third to sixth insulating layers 30 to 60 may include at least one of an inorganic layer or an organic layer. For example, the inorganic layer may include at least one of aluminum oxide, titanium oxide, silicon oxide, silicon oxynitride, zirconium oxide, or hafnium oxide. The organic layer may include at least one of an acrylic resin, a methacrylic resin, a polyisoprene-based resin, a vinyl-based resin, an epoxy-based resin, a urethane-based resin, a cellulose-based resin, a siloxane-based resin, a polyamide-based resin, or a perylene-based resin.

The third insulating layer 30 may be disposed on the second insulating layer 20 and cover the gate electrode GE. The upper electrode UE may be disposed on the third insulating layer 30. The upper electrode UE may overlap the gate electrode GE in a plan view, and the gate electrode GE and the upper electrode UE overlapping each other may form a capacitor.

The fourth insulating layer 40 may be disposed on the third insulating layer 30 and cover the upper electrode UE. The connection electrodes CN1 and CN2 may include a first connection electrode CN1 and a second connection electrode CN2. The first connection electrode CN1 may be disposed on the fourth insulating layer 40. The fifth insulating layer 50 may be disposed on the fourth insulating layer 40 and cover the first connection electrode CN1. The second connection electrode CN2 may be disposed on the fifth insulating layer 50. The sixth insulating layer 60 may be disposed on the fifth insulating layer 50 and cover the second connection electrode CN2. In an embodiment, at least one of the fifth insulating layer 50 or the sixth insulating layer 60 may include an organic layer, cover a step between components disposed thereunder, and provide a flat upper surface. For example, at least one of the fifth insulating layer 50 or the sixth insulating layer 60 may have a planar upper surface.

The first connection electrode CN1 may be electrically connected to the semiconductor pattern SM through a contact hole penetrating the second to fourth insulating layers 20 to 40. The second connection electrode CN2 may be electrically connected to the first connection electrode CN1 through a contact hole penetrating the fifth insulating layer 50.

The first connection electrode CN1 and the second connection electrode CN2 may each include a conductive material. The first connection electrode CN1 and the second connection electrode CN2 may each include gold, silver, copper, aluminum, platinum, molybdenum, or titanium, or an alloy thereof. At least one of the first connection electrode CN1 or the second connection electrode CN2 may include conductive layers having a multi-layered structure. For example, at least one of the first connection electrode CN1 or the second connection electrode CN2 may have a triple-layered structure of titanium/aluminum/titanium. However, an embodiment is not necessarily limited thereto.

According to an embodiment of the circuit element layer DP-CL, at least one of the first connection electrode CN1 or the second connection electrode CN2 may be omitted. For example, the second connection electrode CN2 may be electrically connected to the semiconductor pattern SM through a contact hole penetrating the second to fifth insulating layers 20 to 50. Alternatively, according to an embodiment of the circuit element layer DP-CL, an additional connection electrode connecting the transistor TR and the light-emitting element OL may be further disposed. A method of electrically connecting the light-emitting element OL and the transistor TR may be variously changed according to the number of insulating layers disposed between the light-emitting element OL and the transistor TR and is not limited to any one embodiment.

The light-emitting element layer DP-OL may include the light-emitting element OL and a pixel-defining film PDL. The light-emitting element OL and the pixel-defining film PDL may be disposed on the sixth insulating layer 60. The light-emitting element OL may include a first electrode AE, an emission layer EM, and a second electrode CE.

The first electrode AE may be electrically connected to the second connection electrode CN2 through a contact hole penetrating at least a portion of the sixth insulating layer 60. The first electrode AE may be electrically connected to the transistor TR through the first and second connection electrodes CN1 and CN2.

A pixel opening PX-OP may expose at least a portion of the first electrode AE. The pixel opening PX-OP may be defined in the pixel-defining film PDL. A region of the first electrode AE exposed from the pixel-defining film PDL may correspond to a light-emitting region. The pixel-defining film PDL may include an inorganic layer, an organic layer, or a composite material layer. According to an embodiment, the pixel-defining film PDL may further include a black pigment or black dye.

The emission layer EM may be disposed on the first electrode AE. The emission layer EM may be configured to emit a predetermined color light or light of a predetermined range of wavelengths. The emission layer EM may be disposed in correspondence to the pixel opening PX-OP defined in the pixel-defining film PDL. The light-emitting element OL and the pixel opening PX-OP may be provided in plurality, and emission layers EM of the light-emitting elements OL may be disposed in correspondence to the pixel openings PX-OP and may be provided in a form of patterns spaced apart from each other. However, an embodiment of the inventive concept is not necessarily limited thereto, and the emission layers EM of the light-emitting elements OL may be formed as an integral common layer.

The second electrode CE may be disposed on the emission layer EM and the pixel-defining film PDL. The second electrode CE may be provided as a common electrode disposed in common in the pixels PX (see FIG. 4).

The light-emitting element OL may further include at least one of a hole control region disposed between the first electrode AE and the emission layer EM, or an electron control region disposed between the emission layer EM and the second electrode CE. The hole control region may include at least one of a hole generation layer, a hole transport layer, or an electron blocking layer, and the electron control region may include at least one of an electron generation layer, an electron transport layer, or a hole blocking layer.

The encapsulation layer ECL may be disposed on the light-emitting element layer DP-OL. The encapsulation layer ECL may encapsulate the light-emitting element OL. The encapsulation layer ECL may be disposed on the light-emitting element OL and the pixel-defining film PDL, and may encapsulate the light-emitting element OL. The encapsulation layer ECL may include at least one of an inorganic film or an organic film. In an embodiment, the encapsulation layer ECL may include a first inorganic film EN1, a second inorganic film EN3, and an organic film EN2 disposed between the first and second inorganic films EN1 and EN3. However, a configuration of the encapsulation layer ECL is not necessarily limited thereto.

The first inorganic film EN1 may be disposed on the second electrode CE, and the organic film EN2 and the second inorganic film EN3 may be sequentially disposed on the first inorganic film EN1 in a thickness direction of the display panel DP. The first and second inorganic films EN1 and EN3 may protect the light-emitting element OL from moisture or oxygen introduced from the outside. For example, the first and second inorganic films EN1 and EN3 may each include at least one of silicon nitride, silicon oxynitride, silicon oxide, titanium oxide, or aluminum oxide. However, a material of the first and second inorganic films EN1 and EN3 is not necessarily limited to examples described herein. The organic film EN2 may inhibit or prevent foreign substances from being introduced into the light-emitting element OL and cover a step of components disposed below the organic film EN2. For example, the organic film EN2 may include an acrylic organic material. However, a material of the organic film EN2 is not necessarily limited to examples described herein.

The input sensing unit ISP may be disposed on the display panel DP. For example, the input sensing unit ISP may be disposed on the encapsulation layer ECL of the display panel DP. The input sensing unit ISP may include a base layer IL1, a first sensing insulating layer IL2, a first sensing conductive layer CL1, and a second sensing conductive layer CL2. The input sensing unit ISP may further include the second sensing insulating layer IL3 (see FIG. 3) as illustrated in FIG. 3. Descriptions of FIG. 3 may be equally applied to the components of FIG. 6, and repetitive descriptions may be simplified or omitted.

The base layer IL1 may be in contact with an uppermost layer of the encapsulation layer ECL. For example, the base layer IL1 may be in contact with the second inorganic film EN3 of the encapsulation layer ECL. The base layer IL1 of the input sensing unit ISP may be directly disposed on a base surface provided by the encapsulation layer ECL. However, an embodiment of the inventive concept is not necessarily limited thereto, and according to an embodiment, the base layer IL1 may be omitted, and in this case, the first sensing conductive layer CL1 of the input sensing unit ISP may be in contact with the encapsulation layer ECL.

The first sensing conductive layer CL1 may be disposed on the base layer IL1, and the second sensing conductive layer CL2 may be disposed on the first sensing insulating layer IL2. The first sensing conductive layer CL1 and the second sensing conductive layer CL2 may constitute a sensing electrode TE. The sensing electrode TE may correspond to any one of the first or second sensing electrodes TEX and TEY (see FIG. 5) described herein. For example, the first sensing conductive layer CL1 may include a connection pattern CP of the sensing electrode TE, and the second sensing conductive layer CL2 may include a sensing pattern SP of the sensing electrode TE. However, an embodiment of the inventive concept is not necessarily limited thereto, and the first sensing conductive layer CL1 may include the sensing pattern SP, and the second sensing conductive layer CL2 may include the connection pattern CP.

The connection pattern CP may correspond to the first connection pattern CP (see FIG. 5) or the second connection pattern CP2 (see FIG. 5) described herein, and the sensing pattern SP may correspond to the first sensing pattern SP1 (see FIG. 5) or the second sensing pattern SP2 (see FIG. 5) described herein. The connection pattern CP may be disposed on a layer different from that of the sensing pattern SP and may be connected to the sensing pattern SP through a contact hole penetrating the first sensing insulating layer IL2. However, an embodiment of the inventive concept is not necessarily limited thereto, and the connection pattern CP and the sensing pattern SP may be disposed at the same layer and may be integrally formed.

The sensing electrode TE may be a mesh-shaped pattern. The sensing electrode TE may be disposed in correspondence to a region in which the pixel-defining film PDL is disposed. However, an embodiment of the inventive concept is not necessarily limited thereto, and the sensing electrode TE may be provided as a single-shaped pattern overlapping the light-emitting element OL, and in this case, the sensing electrode TE may include a transparent conductive material.

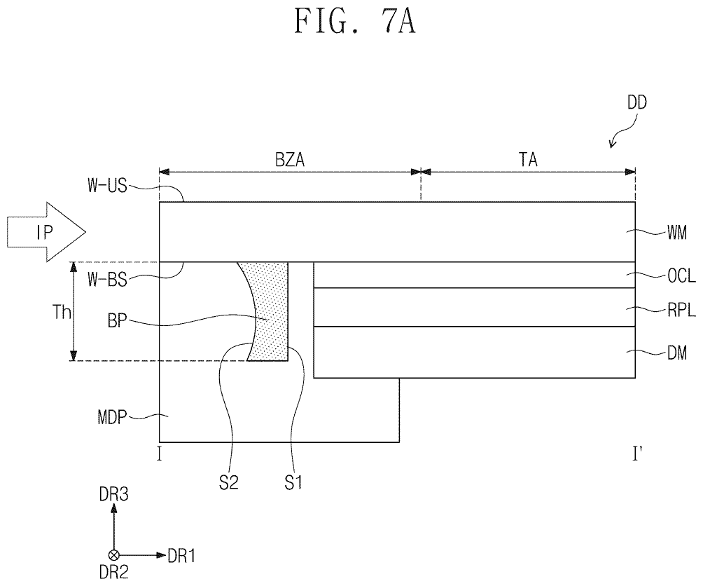

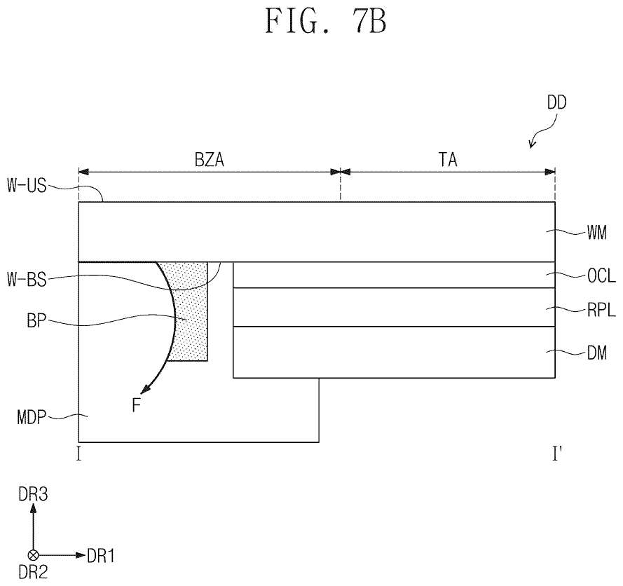

FIG. 7A is a cross-sectional view of a display device of the inventive concept taken along line I-I of FIG. 2. FIG. 7B is a diagram for describing a function of a blocking part illustrated in FIG. 7A. Hereinafter, repetitive descriptions of the contents described elsewhere herein may be simplified or omitted.

Referring to FIG. 7A, an adhesive layer OCL may be disposed between an optical layer RPL and a window WM. The adhesive layer OCL may be omitted, and the optical layer RPL and the window WM may be in direct contact with each other. For example, the optical layer RPL may be disposed on a lower surface W-BS of the window WM. It is illustrated that the optical layer RPL is directly disposed on a display module DM, but an embodiment of the inventive concept is not limited thereto. For example, a separate adhesive layer may be further disposed between the display module DM and the optical layer RPL. That is, the display module DM may be attached to the optical layer RPL through an adhesive layer.

According to an embodiment of the inventive concept, a display device DD of the inventive concept may include a first blocking part BP and a molding part MDP. The first blocking part BP and the molding part MDP may be disposed on the lower surface W-BS of the window WM. The molding part MDP may cover the first blocking part BP below the window WM. The first blocking part BP and the molding part MDP may be disposed to surround at least a portion of the optical layer RPL on the display module DM. For example, the first blocking part BP and the molding part MDP may be disposed along the long sides of the electronic device ED extending in the second direction DR2 and along the short sides of the electronic device ED extending in a first direction DR1, but an embodiment of the inventive concept is not limited thereto. For example, the first blocking part BP and the molding part MDP may be omitted from a portion of the window WM. For example, the first blocking part BP and the molding part MDP may be omitted from a portion of the window WM disposed along a short side of the electronic device ED extending in a first direction DR1 and disposed proximate to the bending region BA. For example, the first blocking part BP and the molding part MDP may be disposed in a portion of the second first short side at the first base region AA1 exposed by the width of the bending region BA and may be omitted from a portion overlapping the bending region BA in the second direction DR2. In an embodiment, the molding part MDP may be disposed to surround a greater portion of the optical layer RPL on the display module DM than the first blocking part BP. For example, the molding part MDP may completely surround the optical layer RPL, and the first blocking part BP may be omitted from a region crossing the signal lines, for example, to reduce or eliminate a force being propagated towards the signal lines. The first blocking part BP and the molding part MDP may each overlap a bezel region BZA of the window WM. However, the inventive concept is not necessarily limited thereto, and the molding part MDP may be disposed in a portion of a transmission region TA of the window WM.

The window WM may include an upper surface W-US and the lower surface W-BS disposed oppose the upper surface W-US. Each of the first blocking part BP and the molding part MDP may be directly disposed on a portion of the lower surface W-BS of the window WM. According to an embodiment of the inventive concept, a degree of adhesion between the first blocking part BP and the lower surface W-BS of the window WM may be different from a degree of adhesion between the molding part MDP and the lower surface W-BS of the window WM. For example, the degree of adhesion between the first blocking part BP and the lower surface W-BS of the window WM may be greater than the degree of adhesion between the molding part MDP and the lower surface W-BS of the window WM. As a result, even if a force is applied to the molding part MDP from the outside, e.g., an impact, the molding part MDP and the first blocking part BP may be prevented from being separated from the lower surface W-BS of the window WM.

The first blocking part BP may overlap at least a portion of the display module DM in the first direction DR1. A thickness Th of the first blocking part BP in the third direction DR3 may be greater than a thickness of the display module DM. The thickness Th of the first blocking part BP may be less than a sum of thicknesses of the display module DM, the optical layer RPL, and the adhesive layer OCL. However, the inventive concept is not necessarily limited thereto, and the thickness Th of the first blocking part BP may be greater than a sum of thicknesses of the display module DM, the optical layer RPL, and the adhesive layer OCL.

The first blocking part BP may be formed using a photocurable resin composition. According to an embodiment of the inventive concept, hardness of the first blocking part BP and hardness of the molding part MDP may be different from each other. For example, hardness of the first blocking part BP may be greater than hardness of the molding part MDP. For example, the molding part MDP may have a hardness between about 10 to about 80 megapascals (MPa) and the first blocking part BP may have a hardness between about 50 to about 130 MPa. For example, hardness of the first blocking part BP may be about 10% greater than hardness of the molding part MDP, or may be about 25% greater than hardness of the molding part MDP, may be about 50% greater than hardness of the molding part MDP. The first blocking part BP may include a first surface S1 and a second surface. The first surface S1 may have the display module DM. The second surface S2 may be disposed opposite to the first surface S1 in the first direction DR1. According to an embodiment of the inventive concept, the second surface S2 may include a curved surface. For example, the second surface S2 may have a shape recessed in the first direction DR1. For example, the second surface S2 may have a concave shape in the first direction DR1.

Referring to FIG. 7A and FIG. 7B together, impact IP may be applied to the display device DD in the first direction DR1 from the outside. For example, the impact IP may be applied to at least one of the window WM of the molding part MDP of the display device DD in the first direction DR1. Since the first blocking part BP of the inventive concept includes the second surface S2 having a curved surface and has higher hardness than the molding part MDP, at least a portion of the impact IP, from the outside, moving in the first direction DR1 may impart a force F along the second surface S2 of the first blocking part BP, and a direction of the force F may be different than a direction of the impact IP. For example, a propagation direction of the impact IP may be changed to be a direction of the force F. For example, a propagation direction of at least a portion of the impact IP may be changed to be the direction of the force F that may be away from the display module DM. For example, an effect of the impact IP from the outside applied to the display module DM of the inventive concept through the first blocking part BP may be reduced or prevented. As a result, a defect such as detachment of the display module DM from the optical layer RPL due to the impact IP from the outside may be inhibited or prevented, and thus the display device DD having reliability may be provided.

The molding part MDP of the inventive concept may include a different material from the first blocking part BP. The molding part MDP may be formed using a photocurable resin composition. The molding part MDP may be formed after the first blocking part BP is formed on the lower surface W-BS of the window WM as a unit. In an alternative, the molding part MDP may be formed around the first blocking part BP, and the molding part MDP and the first blocking part BP may be adhered to the lower surface W-BS of the window WM as a unit. The molding part MDP may adhere to the lower surface W-BS of the window WM, but the lower surface W-BS of the window WM may be detached due to the impact IP from the outside. Since the degree of adhesion between the first blocking part BP of the inventive concept and the lower surface W-BS of the window WM is formed to be greater than the degree of adhesion between the molding part MDP and the lower surface W-BS of the window WM, even if the impact IP from the outside is applied to the molding part MDP, the first blocking part BP may not be separated from the lower surface W-BS of the window WM, and thus the molding part MDP may be inhibited or prevented from being detached from the lower surface W-BS of the window WM.

The molding part MDP may overlap the bezel region BZA. The molding part MDP may cover at least a portion of the display module DM. For example, the molding part MDP may cover a side surface of the display module and at least a portion of a rear surface of the display module DM. For example, the molding part MDP may be disposed in at least a portion of the peripheral region NAA (see FIG. 2) of the display module DM. The inventive concept is not necessarily limited thereto, and the molding part MDP may overlap a portion of the transmission region TA and the bezel region BZA.

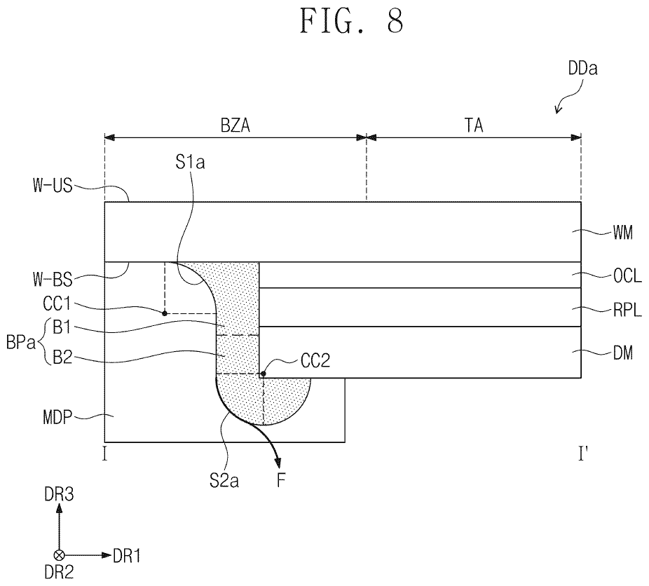

FIG. 8 is a cross-sectional view of a second display device DDa according to an embodiment of the inventive concept. Hereinafter, repetitive descriptions of the content described elsewhere herein may be simplified or omitted.

Referring to FIG. 8, a second blocking part BPa may cover a side surface of a display module DM. For example, the second blocking part BPa may cover at least a portion of a lower surface of the display module DM and the side surface of the display module DM. The second blocking part BPa may overlap the display module DM, an optical layer RPL, and an adhesive layer OCL in the first direction DR1. A thickness of the second blocking part BPa may be greater than a sum of thicknesses of the display module DM, the optical layer RPL, and the adhesive layer OCL. For example, the second blocking part BPa may extend from a lower surface of the display module DM in a direction opposite to the third direction DR3.

According to an embodiment of the inventive concept, the second blocking part BPa may include a first portion B1 proximate to a window WM and a second portion B2 extending from the first portion B1 in a direction opposite to the third direction DR3. The first portion B1 may be in contact with a lower surface W-BS of the window WM. The first portion B1 may include a first curved outer surface S1a, and the second portion B2 may include a second curved outer surface S2a. The second curved outer surface S2a may extend from the first curved outer surface S1a. The first curved outer surface S1a and the second curved outer surface S2a may be each spaced apart from the display module DM. An end portion of the second curved outer surface S2a may extend from the rear surface of the display module DM. The first curved outer surface S1a may be referred to as an outer side surface of the first portion B1, and the second curved outer surface S2a may be referred to as an outer side surface of the second portion B2.

The first curved outer surface S1a may include a curved surface having a first center of curvature CC1 and the second curved outer surface S2a may include a curved surface having a second center of curvature CC2. The first center of curvature CC1 may be disposed in a direction opposite to the first direction DR1 with respect to the first curved outer surface S1a. That is, the first curved outer surface S1a may have a surface concave with respect to the first direction DR1. The second center of curvature CC2 may be disposed in the first direction DR1 with respect to the second curved outer surface S2a. That is, the second curved outer surface S2a may have a surface convex with respect to the first direction DR1. The force F due to the impact IP (see FIG. 7B) from the outside may move along the first curved outer surface S1a and the second curved outer surface S2a of the second blocking part BPa, and a propagation direction of the impact IP may be changed.

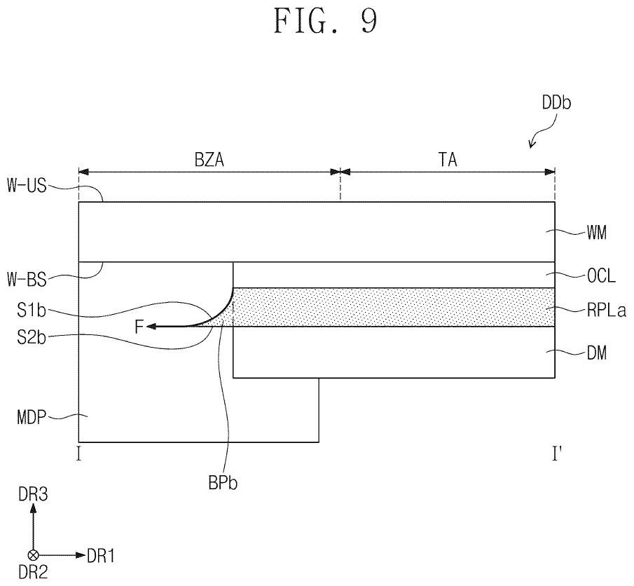

FIG. 9 is a cross-sectional view of a third display device DDb according to an embodiment of the inventive concept.

Referring to FIG. 9, a third blocking part BPb may protrude from an second optical layer RPLa. Specifically, the third blocking part BPb may protrude from the second optical layer RPLa in a direction opposite to the first direction DR1. The third blocking part BPb may be a component included in the second optical layer RPLa. The third blocking part BPb may be spaced apart from a window WM. For example, the third blocking part BPb may be spaced apart from a lower surface W-BS of the window WM in the third direction DR3.

The third blocking part BPb may include a first surface S1b facing the lower surface W-BS of the window WM and a second surface S2b opposed to the first surface S1b. According to an embodiment of the inventive concept, the first surface S1b may include a curved surface. For example, the first surface S1b may have a shape recessed in the third direction DR3. Hardness of the third blocking part BPb may be greater than hardness of a molding part MDP. The third blocking part BPb may have a structure extending from the second optical layer RPLa and include the same material as the second optical layer RPLa. Thus, hardness of the second optical layer RPLa may be greater than hardness of the molding part MDP. That is, the force F due to the impact IP (see FIG. 7B) from the outside may move along the first surface S1b of the third blocking part BPb protruding from the second optical layer RPLa, and a direction of the impact IP may be changed.

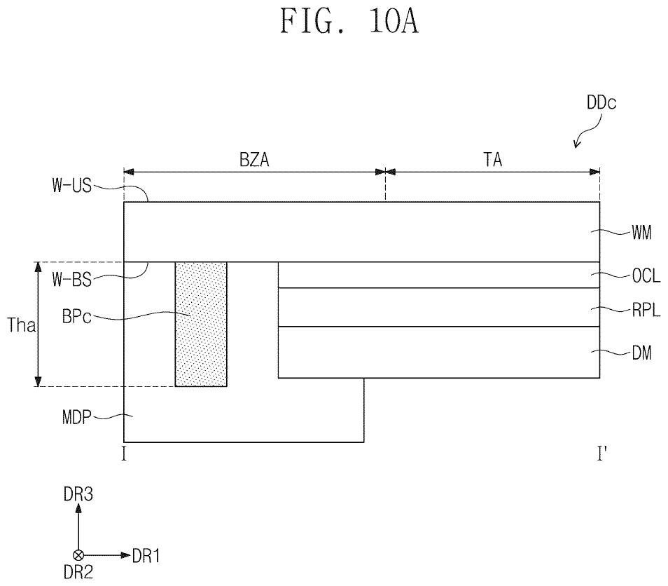

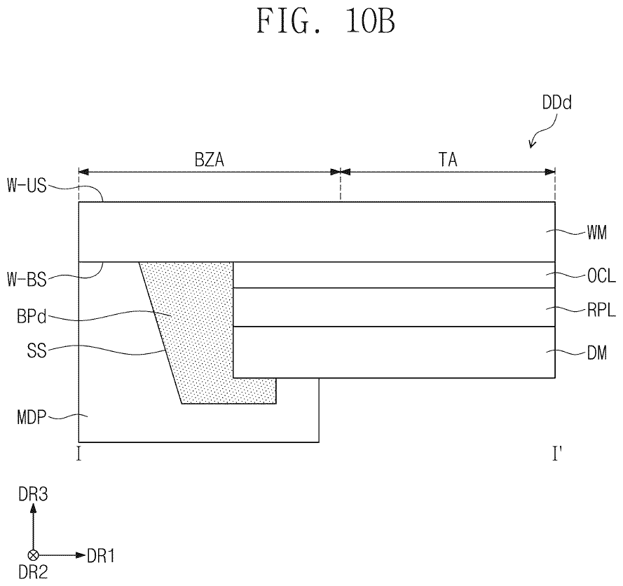

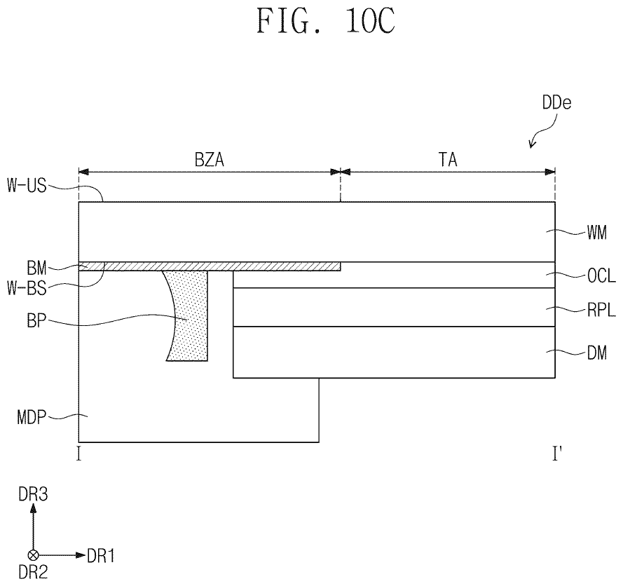

FIG. 10A is a cross-sectional view of a fourth display device DDc according to an embodiment of the inventive concept.

Referring to FIG. 10A, a thickness Tha of a fourth blocking part BPc of the inventive concept may be greater than a sum of thicknesses of a display module DM, an optical layer RPL, and an adhesive layer OCL. That is, the fourth blocking part BPc may completely overlap the display module DM, the optical layer RPL, and the adhesive layer OCL in the first direction DR1.

The fourth blocking part BPc may be spaced apart from the display module DM in the first direction DR1. The fourth blocking part BPc may not include a curved surface. The fourth blocking part BPc may include two side surfaces facing each other in the first direction DR1, and the two side surfaces may each extend in the third direction DR3.

FIG. 10B is a cross-sectional view of a fifth display device DDd according to an embodiment of the inventive concept.

Referring to FIG. 10B, a fifth blocking part BPd may cover a side surface of a display module DM. For example, the fifth blocking part BPd may cover at least a portion of a lower surface of the display module DM and the side surface of the display module DM. The fifth blocking part BPd may overlap the display module DM, an optical layer RPL, and an adhesive layer OCL in the first direction DR1. A thickness of the fifth blocking part BPd may be greater than a sum of thicknesses of the display module DM, the optical layer RPL, and the adhesive layer OCL.

The fifth blocking part BPd may include an outer side surface SS spaced apart from the display module DM. The outer side surface SS may include an inclined surface that is inclined in the first direction DR1. For example, a width of the fifth blocking part BPd in the first direction DR1 may decrease with distance from the lower surface W-BS of the window WM. The impact IP (see FIG. 7B) from the outside may move along the outer side surface SS of the fifth blocking part BPd, and a direction of the impact IP may be changed.

FIG. 10C is a cross-sectional view of a sixth display device DDe according to an embodiment of the inventive concept.

Referring to FIG. 10C, the sixth display device DDe of the inventive concept may include a light blocking pattern BM disposed on a lower surface W-BS of a window WM. A portion of the light blocking pattern BM may be disposed between the lower surface W-BS of a window WM and the adhesive layer OCL. The light blocking pattern BM may overlap a bezel region BZA of the window WM. An area occupied by the light blocking pattern BM in a plan view may correspond to the bezel region BZA. For example, a portion of the light blocking pattern BM may overlap the display module DM, the optical layer RPL, and the adhesive layer OCL. The light blocking pattern BM may be a rigid substrate including a material having a predetermined color. The light blocking pattern BM may include a light blocking material, and a component disposed below the light blocking pattern BM may be shielded from being viewed from the outside. The light blocking material may be a black-colored resin through which light may not be transmitted. The light blocking pattern BM may include at least one of a colored color layer or a black light blocking layer. The light blocking pattern BM may include a plurality of light blocking layers as needed. The light blocking pattern BM may be disposed on the window WM through deposition, printing, coating, or the like.

A first blocking part BP and a molding part MDP may each be directly disposed on a lower surface of the light blocking pattern BM. In this case, a degree of adhesion between the first blocking part BP and the light blocking pattern BM may be greater than a degree of adhesion between the molding part MDP and the light blocking pattern BM.

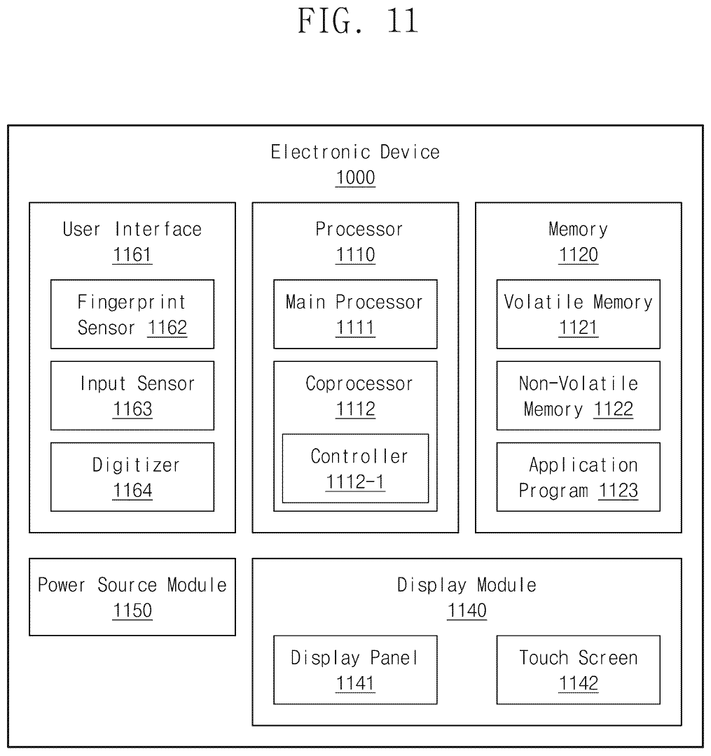

FIG. 11 is a diagram illustrating an electronic device according to an embodiment of the present invention. Referring to FIG. 11, the electronic device 1000 according to one embodiment of the present invention may correspond to the electronic device ED shown in FIG. 1. The electronic device 1000 according to one embodiment of the present invention may output various information (e.g., images, text, music, etc.) through a display module 1140, which, for example, may correspond to the display device DD shown in FIG. 2. When a processor 1110 executes an application stored in a memory 1120, the display module 1140 may provide application information to a user through a display panel 1141.

In some embodiments, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action may activate the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device DD shown in FIG. 2.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 may include the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display device DD shown in FIG. 2.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

A display device of the inventive concept may include a blocking part disposed below a window and a molding part covering the blocking part. Hardness of the blocking part may be greater than hardness of the molding part, and a side surface of the blocking part may include a curved surface, and thus impact from the outside may be prevented from being applied to a display module, and thus a display device having reliability may be provided.

Although description has been made with reference to embodiments of the inventive concept, it is understood that the inventive concept should not be limited, but various changes and modifications may be made by one ordinary skilled in the art within the spirit and scope of the inventive concept as hereinafter claimed.

Therefore, the technical scope of the inventive concept is not limited to the contents described in the detailed description of the specification, but should be determined by the accompanying claims.

What is claimed is:

1. A display device comprising:
a display module;
a window disposed on the display module and including a transmission region and a bezel region disposed proximate to the transmission region;
a blocking part disposed below the window and overlapping the bezel region; and
a molding part disposed below the window and covering the blocking part,
wherein a hardness of the blocking part is greater than a hardness of the molding part.

2. The display device of claim 1, wherein the window comprises an upper surface and a lower surface disposed opposite to the upper surface, and
each of the blocking part and the molding part is directly disposed on the lower surface of the window.

3. The display device of claim 2, wherein a degree of adhesion between the blocking part and the lower surface of the window is greater than a degree of adhesion between the molding part and the lower surface of the window.

4. The display device of claim 1, wherein the blocking part comprises:
a first surface facing the display module; and
a second surface disposed opposite to the first surface, and
the second surface includes a curved surface.

5. The display device of claim 4, wherein the curved surface is recessed in a direction toward the display module.

6. The display device of claim 1, wherein the blocking part covers a side surface of the display module.

7. The display device of claim 6, wherein the blocking part comprises:
a first portion adjacent to the window; and
a second portion extending from the first portion in a thickness direction of the display module.

8. The display device of claim 7, wherein the first portion includes a curved outer side surface and the second portion includes a curved outer side surface.

9. The display device of claim 8, wherein a center of curvature of the curved outer side surface of the first portion is positioned in a direction opposite to a direction in which the display module is disposed with respect to the first portion, and
a center of curvature of the curved outer side surface of the second portion is positioned in a direction in which the display module is disposed with respect to the second portion.

10. The display device of claim 6, wherein a thickness of the blocking part is greater than a thickness of the display module.

11. The display device of claim 10, wherein the blocking part covers a portion of a lower surface of the display module.

12. The display device of claim 1, further comprising:
an optical layer disposed on the display module; and
an adhesive layer disposed on the optical layer and between the optical layer and the window.

13. The display device of claim 12, wherein the blocking part extends from the optical layer, and
a side surface of the blocking part comprises a curved surface.

14. The display device of claim 13, wherein hardness of the optical layer is greater than hardness of the display module.

15. The display device of claim 1, wherein the molding part overlaps the bezel region of the window and covers a portion of a lower surface of the display module.

16. A display device comprising:
a display module;
a window disposed on the display module and including a transmission region and a bezel region surrounding at least a portion of the transmission region;
a blocking part disposed below the window and overlapping the bezel region; and
a molding part disposed below the window and covering the blocking part,
wherein the blocking part includes a first surface facing the display module and a second surface disposed opposite to the first surface, and
the second surface includes a curved surface.

17. The display device of claim 16, wherein a hardness of the blocking part is greater than a hardness of the molding part.

18. The display device of claim 16, wherein the window comprises an upper surface and a lower surface disposed opposite to the upper surface, and
each of the blocking part and the molding part is directly disposed on the lower surface of the window
wherein a degree of adhesion between the blocking part and the lower surface of the window is greater than a degree of adhesion between the molding part and the lower surface of the window.

19. The display device of claim 16, wherein the blocking part is disposed on a first portion of a lower surface of the window and is omitted from a second portion of the lower surface of the window.

20. An electronic device comprising:
a housing;
an electronic module disposed in the housing; and
a display device electrically connected to the electronic module,
wherein the display device includes:
a display module;
a window disposed on the display module and including a transmission region and a bezel region disposed proximate to the transmission region;
a blocking part disposed below the window and overlapping the bezel region; and
a molding part disposed below the window and covering the blocking part,
wherein a hardness of the blocking part is greater than a hardness of the molding part.
